(19) United States
(12) Patent Application Publication
(10) Pub. No.: US 2024/0018674 A1
(43) Pub. Date: Jan. 18, 2024

(54) CATALYST, ELECTRODE AND MANUFACTURING METHODS THEREOF

(71) Applicants: CENTRE NATIONAL DE LA RECHERCHE SCIENTIFIQUE, Paris (FR); ECOLE NATIONALE SUPERIEURE DE CHIMIE DE RENNES, Rennes (FR); UNIVERSITE D'AIXMARSEILLE, Marseille (FR); UNIVERSITE DE RENNES, Rennes (FR); INSTITUT NATIONAL DES SCIENCES APPLIQUEES DE RENNES, Rennes (FR)

(72) Inventors: Maxime DUFOND, Suresnes (FR); Jean Manuel DECAMS, Jacou (FR); Lionel SANTINACCI, Le Beausset (FR); Gabriel LOGET, Rennes (FR)

(73) Assignees: CENTRE NATIONAL DE LA RECHERCHE SCIENTIFIQUE, Paris (FR); ECOLE NATIONALE SUPERIEURE DE CHIMIE DE RENNES, Rennes (FR); UNIVERSITE D'AIXMARSEILLE, Marseille (FR); UNIVERSITE DE RENNES, Rennes (FR); INSTITUT NATIONAL DES SCIENCES APPLIQUEES DE RENNES, Rennes (FR)

(21) Appl. No.: 18/038,529

(22) PCT Filed: Nov. 29, 2021
(86) PCT No.: PCT/EP2021/083364

§ 371 Date: May 24, 2023

(30) Foreign Application Priority Data
Nov. 30, 2020 (FR) FR2012425

(51) Int. Cl. C25B 11/089; C25B 11/059; C25B 11/087; C23C 16/40; C23C 16/455

(52) U.S. Cl. CPC C25B 11/089; C25B 11/059; C25B 11/087; C23C 16/405; C23C 16/406; C23C 16/45555

(57) ABSTRACT

The invention relates to the use of a ternary alloy having the formula SiₓTi_{y}Ni_{z}, wherein x, y and z are natural numbers, for use in electrolysis and photoelectrolysis, in particular photo-oxidation of water. One aspect of the invention relates to a method for the manufacture of an electrode, the method comprising a step of heating a carrier comprising a surface having a layer of silicon on which a layer of TiO₂ is disposed, the layer of TiO₂ being covered with a layer of NiO; the heating step being carried out at a temperature above 1,000° C., and preferably between 1,150° C. and 1,250° C. The invention also relates to an electrode comprising a carrier, said electrode having either: an outer surface on which particles of a ternary alloy having the formula SiₓTi_{y}Ni_{z} are positioned, wherein x, y and z are natural numbers, and wherein the particles form protrusions; or an outer surface consisting of a layer of said alloy, the layer comprising protrusions.

### FIELD OF THE INVENTION

The invention relates to the field of electrodes and electrochemical catalysts, in particular for photoelectrodes and more particularly still to the field of catalysts for photoelectrodes for the photoelectrolysis of water. The invention also relates to a method for manufacturing them.

### PRIOR ART

The photoelectrolysis of water appears to be a promising means of producing solar fuels, such as dihydrogen, which makes it possible to store and transport a high energy density. This production method is renewable and generates gases that can be used directly in fuel cells without forming greenhouse gases. The photoelectrolysis of water therefore allows the transformation of renewable but intermittent energy into an energy reserve that can be stored and transported. At the present time, the cost of this separation is even greater than that obtained from fossil fuels. The separation of water is based on the production of two complementary reactions: the reduction of water (formation of H₂) and the oxidation of water (formation of O₂). The two photo-reactions constitute sizable challenges. Furthermore, the photo-oxidation of water, requiring 4 elementary charges, is particularly limiting.

The electrodes of the photo-electrolyzers mainly consist of a (semiconductor) absorber and a catalyst. It should however be noted that the semiconductor may also act as a catalyst (or co-catalyst). One of the keys to an acceptable cost lies in combining efficient and inexpensive materials. The catalysts that are most commonly used for the reduction and oxidation of water are, respectively, Pt and IrO₂. They are particularly rare and expensive. Pd and RuO₂ are possible substitutes, but they suffer from the same drawbacks. Although the necessary amounts are tiny and it would be possible to recycle them at the end of life of the devices, the available amounts would not suffice because demand for them is rapidly growing. Indeed, the platinoid metals are already widely used in catalytic converters and fuel cells, which are booming. Abundant transition metals (Ni, Fe or Co) and alloys such as Ni—Mo—Cd are encouraging but they do not achieve sufficient performance.

Silicon-based ternary alloys SiₓTi_{y}Ni_{z} have not been considered in the field of photoelectrolysis. These alloys are generally formed by ball milling or arc fusion. A mixture of Si, Ti and Ni having the desired proportions is melted and a solid material is obtained. Such a material is not well-suited to usage in the field of photoelectrodes. SiTiNi alloys, for example with a 66:17:17 atomic ratio, have been described in patent application EP 2 605 315 A1 thus along with uses thereof for manufacturing electrodes for lithium batteries. Such electrodes comprise an outer surface made up of a polymeric binder wherein particles of these alloys and of a polymeric binder are embedded. SiTiNi alloy particles contain Si crystals of sizes smaller than 50 nm.

Li et al. in the article “Photoelectrochemical Water Splitting Properties of Ti—Ni—Si—O Nanostructures on Ti—Ni—Si Alloy”, Nanomaterials 2017, 7, 359, (11) have described the anodizing of a sheet of a Ti—Ni—Si alloy, used as an absorber mainly containing alloys of Ti₅Si₃ and Ti₂Ni. This sheet is covered with amorphous SiTiNiO nanostructures which, after annealing, become crystalline and contain in particular TiO₂ in anatase and rutile form. The photocurrent density jₚₕ of the photoanode obtained from this material is very low (jₚₕ less than 0.6 mA/cm² at V vs. Ag/AgCl).

There is therefore still a need for low-cost catalysts operating with low overvoltage that improve the stability of the electrodes, in particular the stability of the silicon electrodes and compatible with 3D electrodes.

There is also still a need for new electrodes allowing in particular the photo-oxidation and photoreduction of water with low potential difference (<1.3 V).

Surprisingly and unpredictably, it has been found that an SiₓTi_{y}Ni₇ alloy is a material particularly suitable for electrolysis, and in particular for photoelectrolysis of water. It is an effective catalyst that increases the photo-oxidation photocurrent (jₚₕ). It very significantly reduces the oxidation voltage of the water (where surge) at which the jₚₕ appear and it stabilizes the absorber under the highly alkaline conditions of the reaction. These combined advantages make it possible in particular to obtain a photoelectrode having the performance required to perform the photo-oxidation of water under satisfactory energy conditions, i.e., by applying a particularly low potential (for example, less than 0.4 V vs. Hg/HgO at pH=14), or even considering the absence of external voltage application. When the oxidation potential is decreased, an absorber having a less wide band gap can be used. The photoelectrode can thus absorb a larger amount of light produced by the sun and can generate more H₂ and O₂.

An object of the invention is an electrode comprising a carrier, preferably made of photo-absorber material, this electrode having either an outer surface on which particles of a ternary alloy of formula SiₓTi_{y}Ni_{z} are positioned, wherein x, y and z are natural numbers, and or said particles form protrusions, either an outer surface consisting of a layer of this alloy, said layer comprising protrusions. Alternatively when the carrier is a photo-absorber material and/or the electrode is a photoelectrode, the outer surface of the electrode may comprise, or consist of, a thin film of a ternary alloy with the formula SiₓTi_{y}Ni_{z}. Natural numbers (that is positive, non-zero integers) x, y and z are preferably less than and/or equal to 100, in particular less than or equal to 15.

The determination of x, y, and z for a stable alloy under normal conditions of use is possible by known methods, such as that described, for example in X. Hu, G. Chen, C. Ion, and K. Ni J. Phase Equilibria, 20, 508 (1999), (5bis) which also describes the atomic ratios of the stable phases. Thus, the alloy of formula SiₓTi_{y}Ni_{z}, may advantageously be selected from the group consisting of: SiTiNi, SiTi₂Ni₃, SiTi₆Ni₅, Si₄Ti₄Ni, Si₆Ti₂Ni₂, Si₃Ti₁Ni₁, Si₇Ti₄Ni₄. Si₇Ti₆Ni₁₆, Si₃₇T₁₄N₄₉, Si₁₄Ti₃Ni₃ and Si₇₀Ti₁₅Ni₁₅. Preferably the alloy is selected from the group consisting of SiTiNi, SiTi₂Ni₃, SiTi₆Ni₅, Si₄Ti₄Ni, Si₆Ti₂Ni₂, Si₇Ti₄Ni₄, Si₇Ti₆Ni₁₆, Si₃₇T₁₄Ni₄₉ and Si₇₀Ti₁₅Ni₁₅. Preferably the alloy is selected from the group consisting of SiTiNi, SiTi₂Ni₃, SiTi₆Ni₅, Si₄Ti₄Ni, Si₇Ti₄Ni₄, Si₇Ti₄Ni₄, Si₇Ti₆Ni₁₆, and Si₇₀Ti₁₅Ni₁₅. Advantageously, the atomic proportion of Si in the alloy is at least 60%. Particularly preferably, the alloy is Si₇Ti₄Ni₄. It may be noted that a preferred atomic concentration ratio for this alloy is 46:27:27.

The outer surface of the electrode can therefore have protrusions made of an SiₓTi_{y}Ni_{z} alloy. These protrusions may be SiₓTi_{y}Ni_{z} particles, that is, individual structures that are distinct from the constituent material of the electrode surface. Alternatively, these protrusions may be protrusions of a layer of SiₓTi_{y}Ni_{z} alloy present on the surface. In the latter case, the SiₓTi_{y}Ni_{z} alloy forms an outer layer which, for a photoelectrode, is advantageously very thin. Such a thin layer may have a thickness (excluding the thickness of the protrusions, when present) less than 200 nm. Advantageously, this thickness varies from 50 to 200 nm, in particular from 1 to 100 nm. These two fine structures of the outer surface of the electrode can be obtained by a particularly innovative method which is itself an object of the invention and which is described below.

The protrusions/particles made of SiₓTi_{y}Ni_{z} alloy present on the surface of the electrode preferably have a micrometric or sub-micrometric size, or even nanometric. The size of these protrusions is preferably less than 5 μm, preferably 150 nm to 1 μm.

The particles, or the outer layer of SiₓTi_{y}Ni_{z} alloy may be positioned directly on the carrier or on at least one other layer of material (called intermediate material(s)). It is also envisaged to use multilayer materials, where, for example, the silicon layer comprising the catalyst according to the invention on its surface covers another absorbing material. Such a multilayer electrode also forms part of the invention as well as its manufacturing method.

The electrode as such may be in any particular geometric shape suitable for this use, in particular in the form of sheets, plates, pellets, tubes, etc.

The carrier on which the alloy may be deposited may have a flat or structured surface, for example in the form of pores, tips (nanopikes), silicon micropillars of 8, 20 and 40 μm, according to the structuring methods described above (for example, refs. (1), (2) and (3)). The purpose of this structuring is to increase the active surface of the electrode and/or to capture more incident light and/or to facilitate the collection of photogenerated charges. Particularly preferably, the carrier does not comprise any alloy and/or particles of SiₓTi_{y}Ni_{z}.

The carrier is advantageously chosen in the range of usual “photo-absorber” or “absorber” materials in the manufacture of photoelectrodes. A photo-absorber carrier comprising, or consisting of, silicon, preferably doped, is a particularly advantageous choice since it is a good absorber, can be expensive and, moreover, is particularly stabilized by using the catalyst according to the invention. A doping of type n, for example phosphorous, is preferred.

Other photo-absorbers which can also be used are the following Fe₂O₃, BiVO₄ and TiO₂, alone or in combination with other components. In particular, the reduction in the anodic and cathodic overvoltages of water electrolysis make it possible to use absorbers having a reduced band gap (for example closer to 1 eV) such as GaAs, MoS₂, WS₂, CH₃NH₃PbI₃.

The electrode according to the invention may be a photoelectrode (photocathode or photoanode), in particular an electrode capable of photoreduction or photo-oxidation. The electrode according to the invention can be able to be included in an electrolysis device and in particular a water electrolysis device.

In its most general aspect, the electrode according to the invention can also be used in various electrochemical devices such as electrolysis and/or electrocatalysis devices or a photoelectrochemical cell. Such devices and uses are also objects of the invention.

In addition in its broadest conception, the invention may also be described as a catalytic structure, or catalyst, on a carrier, said catalyst either having an outer surface on which particles of a ternary alloy of formula SiₓTi_{y}Ni_{z} are positioned, wherein x, y and z are natural numbers, and wherein said particles form protrusions, either an outer surface consisting of a layer of this alloy, said layer comprising protrusions. The catalyst according to the invention may have the preferential characteristics described above in relation to the electrode. This catalyst may for example be used as a catalyst for the electrolysis of water. The carrier may be any suitable carrier, including those mentioned above. It may also comprise carbon or steel. Indeed, the deposition of Si on carbon, nickel or steel is possible by CVD and its variants.

A further object of the invention is the use of the ternary alloy of formula SiₓTi_{y}Ni_{z} wherein x, y and z are natural numbers as a catalyst of an electrochemical reaction and/or for photocatalysis, in particular for the photo-oxidation of water.

In particular, this use may comprise the use 1) of a thin, or not, layer 2) of protrusions and/or 3) particles of said alloy on the outer surface of an electrode.

Another particularly preferred object of the invention is a method for the manufacture of a catalyst or an electrode based on SiₓTi_{y}Ni_{z} as described above. The method according to the invention advantageously comprises:

a step of heating a carrier comprising a surface having a layer of silicon on which a layer of TiO₂ is arranged, wherein the TiO₂ layer is covered with a NiO layer; said heating step being carried out at a temperature above 1,000° C., more particularly above or equal to 1,100° C. and preferably from 1,150° C. to 1,2500° C. Preferably, at least one of said layers of TiO₂ and NiO is applied by using the atomic layer deposition (ALD) technique. However other techniques, such as the sol-gel method, can be considered to obtain the TiO₂ and/or NiO layers.

Preferably, said layer of TiO₂ and/or NiO has a thickness ranging from to 100 nm, preferably from 10 to 50 nm.

Preferably, the TiO₂ forming said layer, or film, of TiO₂ is in polycrystalline form, and more particularly of the anatase phase of TiO₂.

Carrier Preparation

The carrier is preferably cleaned, and more particularly degreased, by known methods such as successive ultra-sound baths of solvents such as acetone, ethanol, and isopropanol and optionally rinsed, for example with ultrapure water. It is preferable to remove the native oxide layer, if it is present as in the case of silicon, for example by acid soaking (for example hydrofluoric acid). Alternatively, or additionally, it is also possible to follow the RCA cleaning method or other known methods [10].

Deposition of a TiO₂ Layer

According to a preferred embodiment, a layer of TiO₂ is deposited on the carrier. The thickness of this layer preferably varies from 1 to 150 nm, more particularly from 10 to 70 nm and very preferentially from 36 to 46 nm (for example 41 nm). Such a thickness is advantageous because it makes it possible, in particular in conjunction with a layer of NiO of a judiciously chosen thickness (cf. infra), to obtain the alloy Si₇Ti₄Ni₄ which is a particularly preferred alloy. The thickness of this layer can therefore be adapted to obtain other SiₓTi_{y}Ni; alloys depending on the desired stoichiometry of the alloy.

Such TiO₂ films can advantageously be produced by the well-known ALD deposition technique, of which there are many variants. The principle consists of exposing a surface successively to different chemical precursors in order to obtain ultra-thin layers. The ALD cycle is advantageously composed of two successive injection/exposure/purge sequences, one for each of the precursor compounds of Ti and O. The amount of precursor injected into the reactor under primary vacuum or under atmospheric pressure is determined by the opening time of a fast membrane valve. The transport of precursor is assisted by the use of a carrier gas (by Ar or N₂, preferably argon) whose flow is adjusted according to the geometry of the reaction chamber and the power of the pumping unit. An optional “exposure” step is used during which the pumping system is isolated from the reactor in order to obtain a more uniform film. Advantageously, the last step of the cycle is the purge which has the purpose of eliminating the reaction products and the excess of precursors in order to avoid the reaction with the precursors of the following cycle. The cycle is generally repeated n times to obtain the desired thickness according to the given growth rate depending on the nature of the Ti precursor and the temperature of the reactor in the cycle. The ALD technique used may comprise an injection of the precursor carried out under vacuum (cf. (4)), but other ALD techniques under atmospheric pressure, or the spatial ALD techniques, in solution or by laminar flow, may also be used (see ref. (5) (6), .(7), .(8)), .(9)).

According to a preferred embodiment, the precursor chosen for titanium is titanium tetraisopropoxide (TTIP), tetrakis(dimethylamino)titanium (TDMAT) or TiCl₄. A precursor used for oxygen is water, ozone or dioxygen.

Recrystallization of TiO₂

It has been determined that the TiO₂ film thus formed by ALD is generally amorphous or rather weakly crystalline. A recrystallization step can then be used. However, this step is not considered to be necessary but could be advantageous. Such a recrystallization step may be carried out by heating. This heating can take place in air or in other atmospheres such as N₂/O₂ (80/20), under 02. The temperature is advantageously chosen to be greater than 400° C., for example from 4000° C. to 500° C., preferably to around 450° C. It is preferable for this step to obtain a polycrystalline film of the anatase phase of the TiO₂.

Deposition of a NiO Layer

A NiO layer is advantageously deposited on the layer consisting of the TiO₂, annealed or not. The thickness of this layer preferably varies from 1 to 150 nm, more particularly from 2 to 15 nm and very preferentially from 10 to nm (for example 13 nm). Such a thickness is advantageous because it makes it possible, in particular in conjunction with a layer of TiO₂ of a judiciously chosen thickness (see above), to obtain the alloy Si₇Ti₄Ni₁ which is a particularly preferred alloy. The thickness of this layer can therefore be adapted to obtain other SiₓTi_{y}Ni_{z} alloys depending on the desired stoichiometry of the alloy.

Such NiO films can advantageously also be produced by an ALD technique, as described above. The transport of Ni precursor is advantageously assisted by the injection of a carrier gas (Ar or N₂, preferably argon) whose flow is adjusted according to the geometry of the reaction chamber and the power of the pumping unit. It is also possible to use a bubbler or a vaporization system.

According to a preferred embodiment, the precursor chosen for the nickel is Bis(ethylcyclopentadienyl)nickel (Ni(EtCp)₂) or Bis(cyclopentadienyl)nickel (NiCp₂). A precursor used for oxygen is ozone.

Forming an SiₓTi_{y}Ni_{z} Catalytic Layer

According to the method of the invention, an SiₓTi_{y}Ni_{z} catalytic surface is then formed on the carrier by a step of reducing the layers of TiO₂ and NiO. This reduction step is preferably carried out by heating or heat treatment in a reducing medium or system, for example under a reducing atmosphere. This heat treatment step in a reducing atmosphere may optionally be associated with the use of a neutral gas. The use of dihydrogen diluted in argon is particularly preferable. The heat treatment method may be any known method such as, non-exhaustively, resistive, inductive or radiative heating. The infrared illumination method is preferred because it is fast and precise.

Indeed it is advantageous for the processing to be short-lasting. It may thus be from 0.1 s to 10 hours, preferably from 1 to 600 seconds, for example from 25 to 45 seconds. The treatment temperature is advantageously greater than 1,000° C., which, under identical treatment conditions, results in metal nickel being obtained. This temperature is therefore advantageously chosen in a range from 1,050° C. to 1,400° C., preferably from 1,100° C. to 1,300° C., and in particular from 1,150° C. to 1,250° C. (for example in the vicinity of 1,200° C.). Finally, the reduction step or the heat treatment can be carried out at low pressure. This pressure may, for example, range from 0.01 to 0.5 bars, preferably from 0.05 to 0.2 bar, and more particularly from 0.09 to 0.15 bar. According to a particularly preferred embodiment, a heat treatment is applied to the carrier, the conditions of which are the following:
Temperature: 1,150° C. to 1,250° C.;
Treatment time: around 30 s;
Atmosphere: Argon/H₂ (e.g. 1/1), pressure from 50 to 150 mbar.

According to the method of the invention, submicron sized particles can thus be formed.

According to a particular aspect of the invention described above, the electrode may comprise a light-absorbing carrier other than silicon. Thus, a manufacturing method according to the invention can also comprise a preliminary step wherein a layer of silicon is deposited, for example by Chemical Vapor Deposition (CVD) and variants thereof (for example Low-Pressure CVD or Plasma-Enhanced CVD), on the surface of this other carrier so as to allow the manufacture of a multilayer electrode. Preferably, this other light-absorbing carrier is a material having better photoelectrochemical performance than silicon, such as those described above.

The electrode according to the invention can therefore be carried out without its active surface having binders based on polymeric compounds, and in particular carbon-containing polymeric compounds, such as carboxymethyl cellulose. According to one aspect of the invention, the surface area of the electrode is therefore devoid of carboxymethyl cellulose.

It is thus possible that, preferentially, the surface of the electrode only has compounds selected from the group consisting of metals and metalloids and/or their oxides and, optionally, carbon in elemental or pure form. The metals and semimetals advantageously comprise or consist of nickel, titanium and silicon.

### BRIEF DESCRIPTION OF THE FIGURES

The invention will be better understood on reading the following description given solely by way of example and with reference to the appended drawings in which:

FIG. 1 is a sectional view by Transmission Electron Microscopy (TEM) of the multilayers TiO₂/NiO deposited by ALD on silicon formed in step d of example 1; (b) represents the evolution of the crystalline structure as a function of the annealing conditions under H₂ by X-ray diffraction (XRD); (c) a top view of Si₇Ti₄Ni₄ particles on Si by Scanning Electron Microscopy (SEM) of the material obtained in Example 1; (d) a silicon micropillar covered with Ni particles; (e, f, g, h) a diagram showing a preferred manufacturing mode of the SiₓTi_{y}Ni₇ particles by ALD and heat treatment.

FIG. 2 is a comparison of the photocurrent curves as a function of the potential for a Si electrode covered with Ni, n-Si/TiO₂/Ni and Si₇Ti₄Ni₄ (example 1 according to the invention). The position of the thermodynamic oxidation potential of the water is indicated as a dotted line.

### EXAMPLE 1: MANUFACTURE OF A MATERIAL ACCORDING TO THE INVENTION

During this synthesis, the chemical products used, cited below, to clean the samples are of analytical quality, supplied by Merck.

The chosen carrier was flat n-type silicon wafers (100) doped with phosphorus (resistivity 1-10 Ω·cm) supplied by the company Sil'tronix Silicon Technologies (France).

a) Preparation of Silicon Supports

The wafers were cut into squares of 1.5×1.5 cm² and were degreased in successive ultrasound baths of acetone, ethanol, isopropanol (5 min per bath). The samples are rinsed thoroughly with ultra-pure water (ρ=18.2 MΩ). The native oxide layer is removed by dipping in an aqueous solution of HF (10%) for 30 seconds.

b) Depositing an Amorphous TiO₂ Film on Si

The TiO₂ film is deposited using the ALD technique. The deposition was carried out in a commercial reactor at a temperature of 150° C. (it is generally between 70 and 250° C.) under primary vacuum (residual pressure between 10⁻¹ and 10⁻³ Torr) under an argon carrier gas. The amount of precursor injected is determined by the opening duration of a fast membrane valve. The precursor used is tetrakis(dimethylamino)titanium (TDMAT) for Ti and ultrapure water for oxygen. The TDMAT was supplied by STREM Chemicals with a purity level of 98%. The tanks containing the Ti precursor were kept at 80° C. and the ultrapure water reservoir was left at room temperature (approximately 20° C.).

The transport of precursor is assisted by the use of a carrier gas (in this case argon) whose flow is adjusted according to the geometry of the reaction chamber and the power of the pumping unit. An “exposure” step is used during which the pumping system is isolated from the reactor in order to obtain a more uniform film.

The ALD cycle used in this example is therefore described as follows:
Injection of Ti precursor (TDMAT) (2 s)/Exposure (7 s)/Purge (15 s)
Injection of O precursor (water) (0.2 s)/Exposure (7 s)/Purge (15 s)

The cycle is repeated n times to obtain a thickness of about 40 nm.

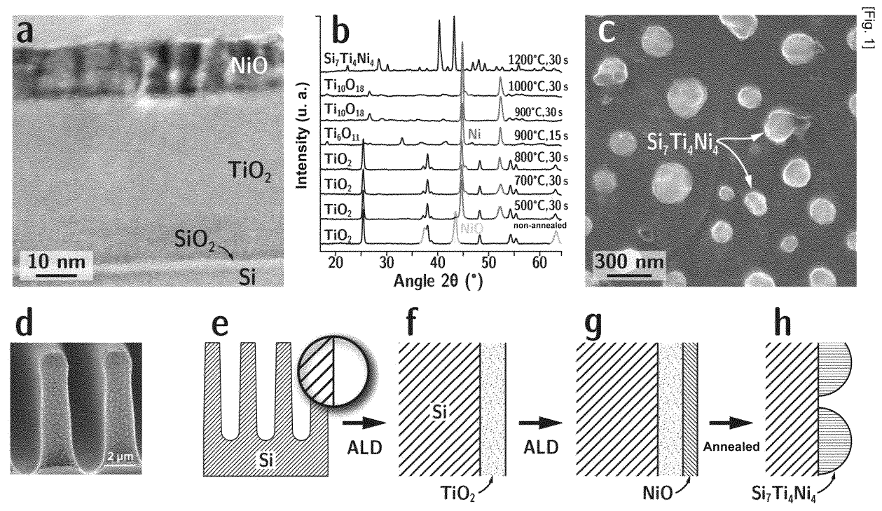

A cross-section of the carrier thus obtained, observed by TEM, is reproduced in FIG. 1a.

c) Recrystallization of TiO₂

The TiO₂ film formed in step 1 is generally amorphous or very slightly crystalline. This film was therefore annealed in air at 450° C. for 2 hours in a furnace. A polycrystalline film of the anatase phase of the TiO₂ is then obtained.

d) Deposition of a Layer of NiO on Si/TiO₂

An NiO film was then deposited on the annealed TiO₂ layer. The ALD technique described for the deposition of the layer of TiO₂ was also used with the same reactor at a temperature of 250° C. The precursor used as a nickel source is Ni (EtCp)₂ and the ozone produced by the generator integrated into the ALD reactor constitutes the oxygen source. The reservoir containing the Ni precursor was maintained at 90° C. for Ni(EtCp)₂. Since this Ni precursor has a low saturated vapor pressure, it was decided to use assistance optimizing their transport from the tank to the reactor. More precisely, the carrier gas (Ar) was injected into the Ni(EtCp)₂ tank before opening the communication valve with the reactor. The ALD cycle consists of two injection/exposure/purge sequences, one for the Ni precursor and the other for the O precursor. The amount of precursor injected into the reactor under primary vacuum (residual pressure of between 10⁻¹ and 10⁻³ Torr) was determined by the opening duration of a fast membrane valve. The ALD cycles are therefore described as follows:
Injection of Ni(EtCp)₂ (2 s)/Exposure (15 s)/Purge (10 s)
Injection of O₃ (0.2-0.3 s)/Exposure (13 s)/Purge (10 s)

The cycle is repeated n times to obtain a thickness of about 13 nm.

e) Manufacturing a Layer of Catalvtic Material Si₇Ti₄Ni₄ by Thermal Processing

The material consisting of the superposition of a nickel oxide film on a titanium oxide film itself placed on a doped silicon carrier was then reduced by annealing under H₂ using the rapid thermal processing by infrared illumination method. The conditions of this reducing thermal processing are as follows:
Temperature: 1,200° C. (temperature rise ramping 20° C./s)
Annealing time: 30 s
Atmosphere: Argon/H₂ (ratio 1/1), pressure of 100 mbar.

This material was identified as being a ternary metal alloy Si₇Ti₄Ni₄ (STN). The identification was performed by XRD as shown in FIG. 1b.

This figure also comprises, for comparison purposes, the obtained diagrams of materials (7×) comprising layers of TiO₂ and NiO superimposed on a carrier obtained according to this example except that the annealing temperature of step e) did not substantially exceed 1,000° C.

The calculations according to the density functional methods (DFT) carried out in the laboratory show that the material according to the invention is metallic. Although the literature on an SiₓTi_{y}Ni_{z} alloy is relatively limited, this is consistent with resistivity measurements performed on a film obtained by physical vapor deposition (PVD).

In addition, on the surface of the material, Si₇Ti₄Ni₄ particles are disposed quite regularly by SEM, as shown in the top view of FIG. 1c. These particles can also be observed in FIG. 1d which shows a material according to the invention which was produced according to example 1 but from a silicon carrier configured in the form of pillars (see FIG. 1e).

These particles of sub-micrometer size increase the active area of the alloy.

### EXAMPLE 2: PHOTOELECTRIC CHARACTERISTIC OF AN ELECTRODE ACCORDING TO THE INVENTION COMPRISING THE MATERIAL OF EXAMPLE 1

The photoelectrochemical characteristics of the material of Example 1 as a photoanode in the photo-oxidation of water were determined under the following conditions:

A three-electrode photoelectrochemical half-cell (photo anode, counter electrode and reference electrode) is equipped with a quartz window. This window allows the UV rays produced by a lamp emitting polychromatic light to reach the surface of the photoanode.

The photoanode consists of the carrier produced in example 1. The counter electrode is a platinum wire, the reference electrode is a Hg/HgO electrode (1 M KOH). A seal with a diameter of 6 mm ensures the sealing of the cell and allows the exposure of 0.28 cm² of the photoanode. The rear contact between the photoanode and the circuit is ensured by a copper disc, after an InGa eutectic produced in-house is applied behind the sample. The whole is connected to a potentiostat (EG&G PAR, Model 273). The light source is a 150 W xenon lamp (Oriel, APEX, ref: 6255) calibrated using a photodiode (Newport, Cell and Meter, ref: 91150V) to obtain a power of 100 mW cm². The electrolyte used was 1 M KOH (pH=14).

Nitrogen (nitrogen U, 99.95%, Air Liquide) is bubbled into the cell before and throughout the duration of the acquisitions in order to evacuate all the oxygen dissolved in the electrolyte.

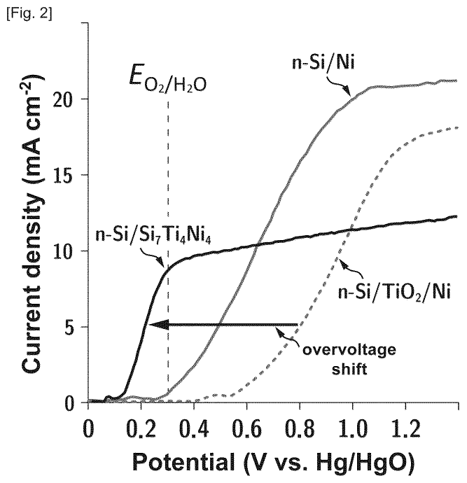

FIG. 2 compares the photoelectrochemical performances (the photocurrents vs. the potential), via the superposition of the voltammograms obtained after several test cycles of the electrodes (these cycles consist of alternating cycling voltammetry phases with open-circuit potential measurement phases for 90 min. under illumination), of this photoanode according to the invention, an n-Si/TiO₂/Ni material (obtained by reductive annealing of NiO at 900° C. for 30 seconds) and an n-Si/Ni material under the same or similar conditions of use.

The material according to the invention does not exhibit the highest current (therefore the production of O₂), but this level is acceptable and can be optimized as it depends greatly on the charge and the geometry of the particles. However, the overvoltage at which the current appears is spectacular. The shifts to the negative voltages (respectively −200 and −400 mV relative to Si/Ni and Si/TiO₂/Ni) are valuable. This is particularly advantageous since the absorption of the solar spectrum goes from being limited to λ<600 nm to a maximum located at λ<950 nm, or an amount of absorbed photons multiplied by 2.5.

Although the comparison is difficult to do with IrO₂ (reference catalyst for the oxidation of water) since it is used in acid solution, the overvoltage obtained with the material according to the invention is comparable. In addition, the material according to the invention is functional in an alkaline medium and its cost is significantly lower. Indeed, like nickel, the alloy makes it possible to perform long (photo-)electrochemical characterizations (about ten hours under illumination) without the Si being harmed.

The invention is not limited to the embodiments presented, and other embodiments will become clearly apparent to those skilled in the art.

### LIST OF REFERENCES

(1) Kern, W. (1990). “The Evolution of Silicon Wafer Cleaning Technology”. Journal of the Electrochemical Society. 137 (6): 1887-1892. doi: 10.1149/1.2086825.
(2) Santinacci, L.; Diouf, M. W.; Barr, M. K. S.; Fabre, B.; Joanny, L.; Gouttefangeas, F.; Loget, G. ACS Appl. Mater. Interfaces 2016, 8 (37), 24810.
(3) Loget, G.; Vacher, A.; Fabre, B.; Gouttefangeas, F.; Joanny, L.; Dorcet, V. Materials Chemistry Frontiers 2017, 1 (9), 1881.
(4) Harding, F. J.; Surdo, S.; Delalat, B.; Cozzi, C.; Elnathan, R.; Gronthos, S.; Voelcker, N. H.; Barillaro, G. ACS Appl. Mater. Interfaces 2016, 8 (43), 29197.
(5) Dufond, M. E.; Diouf, M. W.; Badie, C.; Laffon, C.; Parent, P.; Ferry, D.; Grosso, D.; Kools, J. C.; Elliott, S. D.; Santinacci, L. Chern. Mater. 2020, 32 (4), 1393.
(5bis) X. Hu, G. Chen, C. Ion, and K. Ni J. Phase Equilibria, 20, 508 (1999)
(6) Cowdery-Corvan, P. J et al. U.S. Pat. No. 8,207,063 B2 (2012)
(7) Suntola, T.; Antson, J. U.S. Pat. No. 4,058,430 (1977)
(8) Wu, Y.; Döhler, D.; Barr, M.; Oks, E.; Wolf, M.; Santinacci, L.; Bachmann, J. Nano Lett. 2015, 15, 6379.
(9) Kools, J. C. S. US Patent US10,221,479B2 (2019)
(10) Li at al., “Photoelectrochemical Splitting properties of Ti—Ni—Si—O nanostructures on T-Si—Ni alloy”, nanomaterials 2017, 7,359, doi:10,3390/nano7110359

1. An electrode comprising a carrier the electrode having either an outer surface on which particles of a ternary alloy of formula SiₓTi_{y}Ni_{z} are positioned, wherein x, y and z are natural numbers less than or equal to 100, and wherein the particles form protrusions, either an outer surface consisting of a layer of this alloy, the layer comprising protrusions.

2. The electrode according to claim 1, wherein the electrode is a photoelectrode.

3. The electrode according to claim 1, wherein the electrode is a photocathode.

4. The electrode according to claim 1, wherein the carrier is made of light-absorbing material that comprises silicon.

5. The electrode according to claim 1, wherein the protrusions of the alloy have a size of less than 5 μm.

6. A photoelectrochemical cell comprising an electrode according to claim 1.

7. (canceled)

8. A method for manufacturing an electrode based on a ternary alloy having the formula SiₓTi_{y}Ni_{z}, wherein x, y and z are natural numbers, the method comprising:
a step of heating a carrier comprising a surface comprising a layer of silicon on which a layer of TiO₂ is arranged, the layer of TiO₂ being covered with a layer of NiO; the heating step being carried out at a temperature above 1,000° C.

9. The method according to claim 8, wherein at least one of the layers of TiO₂ and NiO is applied by using the ALD technique.

10. The method according to claim 8, wherein the layer of TIO₂ and/or NiO has a thickness ranging from 10 to 100 nm.

11. (canceled)

12. The electrode according to claim 1, wherein the carrier is made from photoabsorber material.

13. The electrode according to claim 2, wherein the photoelectrode is a photoanode.

14. The electrode according to claim 5, wherein the protrusions of the alloy have a size ranging from 150 nm to 1 μm.

15. The method according to claim 8, wherein the temperature ranges from 1,150° C. to 1,250° C.

16. The method according to claim 10, wherein the thickness ranges from 10 to 50 nm.
